(19) United States
(12) Patent Application Publication
(10) Pub. No.: US 2025/0194033 A1
(43) Pub. Date: Jun. 12, 2025

(54) ELECTRICAL ENCLOSURE INCLUDING IN-MOLD DECORATION

(71) Applicant: ABB Schweiz AG, Baden (CN)

(72) Inventor: Sheng Zhong, Raleigh, NC (US)

(21) Appl. No.: 18/535,850

(22) Filed: Dec. 11, 2023

(51) Int. Cl. H05K 5/02; H05K 5/00; H05K 5/03

(52) U.S. Cl. CPC H05K 5/0243; H05K 5/03; H05K 5/10

(57) ABSTRACT

Systems and apparatuses of an electrical enclosure including a cover plate member including a base material and a film including a plurality of layers. The film may include a first adhesive layer configured to integrally form with the base material and affix the other layers to the base material. The film defining an exterior surface of the cover plate member. The film may further include a graphic layer, a hard coat layer, and a second adhesive layer located therebetween. The graphic layer provides the cover plate member with a decorative surface appearance. The method may include arranging a film in a mold cavity, closing a first mold and a second mold to define a mold cavity, injecting the base material in the mold cavity at a first temperature, and cooling the base material to a second temperature.

### FIELD

The present disclosure relates to the field of electrical enclosures. More particularly, to electrical enclosures including in-mold decoration.

### BACKGROUND

Electrical enclosures are a container that contains electrical equipment and wires. Electrical enclosures typically include an opening for providing access to the electrical equipment and wiring within the container. The electrical enclosure may be installed by attaching the enclosure to a structural member, the electrical enclosure having a cover to conceal the electrical equipment and wiring therein. The outer surface of the cover that may be viewable by persons or users may have a decorative finish applied to the cover.

### SUMMARY

Metal electrical enclosures are commonly used as electrical wall boxes, electrical floor boxes, and the like in high traffic areas, outdoor installations, food and beverage applications, and in corrosive environments. They are utilized in these types of applications due to their high mechanical strength, electrical grounding capability, and desired aesthetic appearance. However, conventional metal electrical enclosures can be difficult to manufacture. In addition, with shortages in supply chains, the manufacturing cost of metallic enclosures has increased relative to historical costs due to these and other factors. Conventional electrical enclosures can have one or more members made of plastic. For example, the electrical wall box cover can be made of a plastic material. The plastic members may have a color as a result of conventional plastic coloring technology, e.g., adding coloring additives that are dispersed through the base plastic material. However, these plastic members of electrical enclosures have a distinctive plastic finish that can be easily distinguished from members made of metallic materials by users.

The various embodiments of the present disclosure relate to systems, apparatus, and methods of manufacturing improved electrical enclosures, or one or more portions thereof, using in-mold decoration (“IMD”) films. The one or more methods described herein enable manufacture of one or more members of a non-metallic electrical enclosure, e.g., box, cover plate, receptacle covers, and other members of the electrical enclosure, the member being formed with the film integrally formed with a base material, the film thereby defining a surface of the electrical enclosure member and providing the member's surface with a decorative finish based on a desired aesthetic appearance. For example, the film may include one or more layers having properties that provide the electrical enclosure with a metallic surface finish (e.g., metallic appearance). The metallic finish may be configured to impart the non-metallic members of electrical boxes or enclosures with a metal aesthetic that may be visually indistinguishable from their metallic counterparts by a user, while lowering the cost to manufacture the electrical enclosures compared to conventional metal electrical enclosures parts. In addition, the non-metallic (e.g., plastic) components may also be designed to include a sufficient mechanical strength to enable utilization based on the specific application.

The non-metallic electrical enclosure members include a base material that defines a body with at least one layer of the film integrally formed with the base material at the body's surface, during the molding process, such that the other layers of the film may be affixed to the body of the electrical enclosure member. By integrally molding the film to the body, extraneous steps such as applying adhesives to bond overlays to the plastic parts may be removed from the manufacturing process. In this regard, the IMD film layer, or at least one layer thereof, may chemical bond with the base material as a result of injecting the base material into a mold having arranged therein the film, the base material being in a flowable state during the injection and then hardening to integrally form into a body with the film (or at least one layer of the film), thereby permanently and securely affixing the film to the base material and thereby rendering it difficult to remove the IMD film.

The film layer can also provide improved abrasion resistance compared to conventional coating methods. The abrasion resistance can also be improved by film design. For example, anti-abrasion polyurethane coating can be added to the hard coat layer. Another approach is to use harder composite film layers to enhance the durability.

The coating materials of the film layers can be selected to be compatible with certain service environments. For example, the film coatings may be selected for having improved corrosion resistive properties for use in corrosive environments.

In addition, the materials of the electrical enclosure members may be selected based on the specific application. For example, the materials may be selected for having one or more desirable structural properties. In addition, the electrical enclosure members themselves may also be designed during the manufacturing stage to include one or more structural features that improve the strength of the member based on the specific application. For example, in one embodiment, the member may be a cover plate for an electrical floor box, and the base materials and film materials of the cover plate may be selected based on the materials structural properties to enable the cover plate to withstand a certain mechanical load and to include a certain level of abrasion resistance from traffic. The cover plate may also be designed during manufacturing to include one or more structural features enhancing its mechanical stiffness to withstand the mechanical load. For example, the cover plate may include one or more ribs traversing the surface of the cover plate opposite the surface having the film.

The electrical enclosures may include one or more members. Each member may be formed to include the base material and the film, the film being integrally formed with the base material surface such that the film defines a surface or surfaces of the member. For example, a floor box enclosure system may include a cover plate member that covers the opening of the housing of the floor box and/or the opening formed in the structural member where the floor box is located, and may also include one or more plate members that cover openings formed in the cover plate member that are configured to provide access to one or more electrical components located in the floor box housing (e.g., electrical receptacles). In addition, for different gangs or different types of electrical components in the enclosure, the shape and dimensions of each member may be modified accordingly.

It is to be appreciated by those having ordinary skill in the art that the shapes and dimensions of the members of the electrical enclosures described herein are exemplary and not intended to be limiting, that is, the members may include any of a plurality of shapes and dimensions in accordance with the present disclosure. In addition, the members may be formed including different types of structural features such as, for example, openings, bores, apertures, recesses, protrusions, embossments, detents, flanges, steps, curves, corners, coves, eased edges, rounded edges, angular edges, other features, or any combinations thereof. In this regard, it is to be appreciated by those having ordinary skill in the art that the members may be manufactured such that the member surface having the film integrally formed therein with the underlying base material may define these different shapes, dimensions, and features.

In some embodiments, a system for an electrical enclosure includes one or more members including a base material, and a film including a plurality of layers. In some embodiments, the film includes a first adhesive layer. In some embodiments, a portion of the first adhesive layer is integrally formed with the base material and affixes the other layers of the film to the base material to define an exterior surface of the one or more members. In some embodiments, the one or more members includes a cover plate member for the electrical enclosure.

In some embodiments, the one or more members further includes at least one plate member for covering an electrical receptacle opening.

In some embodiments, the film further includes a graphic layer. In some embodiments, the graphic layer is disposed on the first adhesive layer opposite the base material. In some embodiments, the graphic layer includes one or more materials having properties configured to provide the exterior surface of the one or more members with a decorative appearance based on the one or more materials.

In some embodiments, the first adhesive layer affixes the graphic layer to the exterior surface of the one or more members.

In some embodiments, the graphic layer includes a metallic material. In some embodiments, the properties of the metallic material are configured to provide the one or more members with a metallic surface.

In some embodiments, the graphic layer includes a plastic material. In some embodiments, the properties of the plastic material are configured to provide the one or more members with a matte surface or a glossy surface.

In some embodiments, the film further includes a hard coat layer. In some embodiments, the hard coat layer includes a transparent or semi-transparent protective layer disposed on a side of the film opposite the first adhesive layer. In some embodiments, the film further includes a second adhesive layer. In some embodiments, the second adhesive layer is arranged between the graphic layer and the hard coat layer.

In some embodiments, the hard coat layer is configured to protect the one or more members and the other layers of the film from ultra-violet radiation, abrasion, dirt, and corrosion. In some embodiments, the second adhesive layer affixes the hard coat layer to the graphic layer.

In some embodiments, the one or more members are formed using a molding process, the molding process including injecting the base material into a mold at a first temperature to enable the portion of the first adhesive layer contacting the base material to integrally fuse with the base material and form a respective member of the one or more members when the base material hardens to a second temperature.

In some embodiments, an apparatus includes an electrical enclosure, the electrical enclosure includes a housing for receiving one or more electrical components therein, and at least one member includes a base plastic material, and a film including a first adhesive layer, and a graphic layer. In some embodiments, a portion of the first adhesive layer is integrally formed with the base plastic material and affixes the graphic layer to the base plastic material to define an exterior surface of the at least one member. In some embodiments, the at least one member includes a first member configured to cover an opening of the housing.

In some embodiments, the graphic layer is disposed on the first adhesive layer opposite the base plastic material. In some embodiments, the graphic layer includes one or more materials having properties configured to provide the exterior surface of the first member with a decorative appearance based on the one or more materials.

In some embodiments, the graphic layer includes at least one of a metallic material, the metallic material including properties configured to provide the exterior surface of the at least one member with a metallic appearance, and a plastic material, the plastic material including properties configured to provide the exterior surface of the at least one member with a matte appearance or a glossy appearance.

In some embodiments, the film further includes a hard coat layer, the hard coat layer includes a transparent or semi-transparent protective layer disposed on a side of the film opposite the first adhesive layer. In some embodiments, the hard coat layer protects the at least one member from ultra-violet radiation, abrasion, dirt, and corrosion, and a second adhesive layer. In some embodiments, the second adhesive layer is arranged between the graphic layer and the hard coat layer to affix the hard coat layer to the graphic layer.

In some embodiments, the at least one member further includes one or more second members, the one or more second members are configured to cover an opening of the first member.

In some embodiments, a method for manufacturing a cover plate member for an electrical enclosure includes arranging a film including a plurality of layers in a first recess of a first mold, closing the first mold and a second mold such that the first recess and a portion of the second mold defines a mold cavity, injecting a base material at a first temperature in the mold cavity at a first side of the film, and cooling the base material to a second temperature to enable the base material to harden and form the cover plate member. In some embodiments, the film defines an exterior surface of the cover plate member. In some embodiments, the film includes a first adhesive layer, and a portion of the first adhesive layer integrally forming with the base material at the first temperature to enable the first adhesive layer to affix the other layers of the film to the exterior surface of the cover plate member.

In some embodiments, the method further includes applying a retaining force onto the film to arrange the film along one or more sides of the first recess, the retaining force includes at least one of mechanical force, electrostatic association, gravity, and vacuum.

In some embodiments, the method further includes ejecting the cover plate member from the mold cavity, the cover plate member is ejected having a first shape, and refining the cover plate member to define a second shape, refining the cover plate member includes removing excess film from one or more edges of the cover plate member having the first shape to define the second shape.

In some embodiments, the first temperature corresponds to a melting temperature of the base material such that the base material includes a flowable material at the first temperature, and the first temperature is greater than a glass transition temperature of the first adhesive layer to enable the first adhesive layer to integrally form with the base material. In some embodiments, the second temperature includes an ejection temperature, the second temperature being below the glass transition temperature of the first adhesive layer.

In some embodiments, the film further includes a graphic layer disposed adjacent the first adhesive layer opposite the base material, the graphic layer includes one or more materials having properties configured to provide the exterior surface of the cover plate member with a decorative appearance based on the one or more materials, a hard coat layer disposed on a side of the film opposite the first adhesive layer, the hard coat layer includes a transparent or semi-transparent protective layer to protect the cover plate member and the other layers of the film, and a second adhesive layer disposed between the graphic layer and the hard coat layer, the second adhesive layer affixes the hard coat layer to the graphic layer.

In some embodiments, the cover plate member includes a first member, and one or more second members, the first member and the one or more second members each includes the film integrally formed with the base material to define the exterior surface of a respective one of the cover plate member.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1A is a first perspective view of a non-limiting example of a system, according to some embodiments.

FIG. 1B is a second perspective view of the system of FIG. 1, according to some embodiments.

FIG. 2 is a partial sectional side view of the system of FIG. 1, according to some embodiments.

FIG. 3A is a partial sectional view of the system from FIG. 2, according to some embodiments.

FIG. 3B is an exploded partial sectional view of the system from FIG. 2, according to some embodiments.

FIG. 4 is a graphical illustration of a non-limiting example of an abrasion resistance of the system of FIG. 1, according to some embodiments.

FIG. 5 is a graphical illustration of another non-limiting example of the abrasion resistance of the system of FIG. 1, according to some embodiments.

FIG. 6A through FIG. 6F are non-limiting examples of the system, according to some embodiments.

FIG. 7 is a flow diagram illustrating a method of manufacturing an electrical enclosure, according to some embodiments.

FIG. 8 is a diagrammatic view of a non-limiting example system for performing the method of FIG. 7, according to some embodiments.

FIG. 9 is a flow diagram illustrating the method of manufacturing the electrical enclosure, according to some embodiments.

FIG. 10 is a flow diagram illustrating the method of manufacturing the electrical enclosure, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

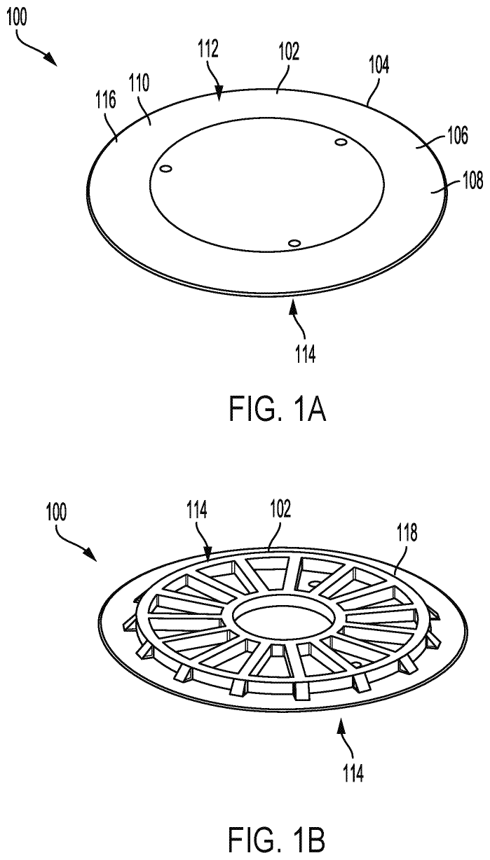

FIG. 1A is a first perspective view of a non-limiting example of system 100, according to some embodiments.

System 100 may include an electrical enclosure such as, for example, an electrical floor box, wall box, outdoor electrical cabinets, and the like. The electrical enclosure may include a member such as, for example, member 102, as will be further described herein. In some embodiments, the system 100 may include one or more members.

The member 102 may include a body 104 and a film 106 disposed on a surface of the body 104. The body 104 may be formed of a base material. In some embodiments, the base material may be a thermoplastic resin material. The base material may include one or more plastic materials formed by any of a plurality of processes including, but not limited to, injection molding, compression molding, extrusion, potting and other like processes. The film 106 may include a plurality of layers, and the film 106 may be integrally formed with the body 104 during a manufacturing of the member 102 such that the film 106 may be affixed to the body 104, as will be further described herein.

The body 104 may be formed during the manufacturing to include a first side 112 and a second side 114, a non-limiting example of the second side 114 is shown in FIG. 1B. It is to be appreciated that the body 104 may include any number of additional sides such as, for example, one or more sidewalls that form the body 104 and define an interior region for receiving and housing electrical components therein. The member 102 may be manufactured such that the film 106 is disposed substantially on one of the first side 112 or the second side 114. In FIG. 1, the member 102 includes the film 106 on the first side 112. In other embodiments, the film 106 may also be disposed on the second side 114. In some embodiments, the film 106 may substantially be disposed on the first side 112 and a portion of the film 106 may extend a perimeter of the first side 112 and onto one or more other sides of member 102 to enable the exterior exposed surfaces of member 102 (e.g., when installed) to provide the desired decorative aesthetic (e.g., appearance), that is, the film 106 provides the outer surfaces of member 102 with an appearance that simulates the member 102 being made of a material having a desired decorative aesthetic. For example, the film 106 may include a graphical layer including metallic materials that provides the appearance that the member 102 is formed of metal.

The materials forming the body 104 may have a certain melting temperature (e.g., first temperature), and the first adhesive layer 108 of the film 106 may have a glass transition temperature less than the melting temperature of the materials of body 104 to enable the first adhesive layer 108 to integrally form with body 104 when the material forming body 104 is in a flowable state. The film 106 integrally forms with the body 104 to form member 102, that is, the first adhesive layer 108 of film 106, or a portion thereof, fuses to the body 104 at the surface of the body 104 when the materials of the body 104 harden to a second temperature, such that the other layers of the film 106 are affixed to the body 104.

In FIG. 1A, member 102 is shown to be a cover plate for an electrical enclosure that is arranged to cover the electrical enclosure opening. In some embodiments, the member 102 may be one or more members of an electrical enclosure. For example, the cover plate may include a first member to cover the opening at the structural member and a second member to cover one or more components of the electrical enclosure, each member being formed to include the film integrally formed on the surface of the respective member. In other embodiments, the member 102 may be the electrical enclosure itself, one or more outer surfaces of the electrical enclosure having the film integrally formed with the surface of the body defining the electrical enclosure. For example, the system 100 may include an electrical box and a cover plate covering an opening of the electrical box and/or an opening at a structural member where the box is installed, and the outer surface of the electrical box and the cover plate may each have the film integrally formed with their respective bodies.

It is to be appreciated by those having ordinary skill in the art that the member 102 shown in the figures is not intended to be limiting any may include any of a plurality of shapes, forms, dimensions, and other structural characteristics in accordance with the present disclosure.

The non-metallic materials of the member 102 (e.g., body 104, one or more layers of film 106) can be formed of thermoplastics, thermoset materials, and the like. The potential thermoplastic materials may include, but is not limited to, polyolefins, such as polypropylene, polyethylene, low density polyethylene (LDPE), high density polyethylene (HDPE), acetal and ketal-based polymers and copolymers, polyesters (e.g. polyethylene terephthalate, polybutylene terephthalate), polycarbonate, Acrylonitrile butadiene styrene (ABS), polystyrene, polyether sulfone (PESU), polyphenylene sulfone (PPSU), polysulfone, and polytetrafluoroethylene (PTFE). Other polymers can also be implemented to form the non-metallic materials including, but is not limited to, polylactic acid, ethylene vinyl acetate copolymer (EVA), polyvinyl chloride (PVC), polyetherimide (PEI), polyphenylene sulfide (PPS), polyether ether ketone (PEEK), polyphthalamide (PPA), polyoxymethylene (POM), phenolformaldehyd (PF), unsaturated polyester (UP), polyurethane (PUR and PU), polyimide, polyamide, polyvinyl alcohol, polyvinylidene chloride, polyacrylonitrile and polyalkylene paraoxybenzoate. The polymer matrix can be a single polymer or any of a combination of these thermoplastics.

The potential thermoset materials may include, but is not limited to, polyester, epoxies, bulk molding compound (BMC), phenolics, polyisoprene, polybutadiene (butadiene rubber), styrene-butadiene rubber, acrylonitrile-butadiene copolymer, isobutylene-isoprene copolymer, ethylene-propylene copolymer, polychloroprene, polysulfide, polydimethyl siloxane (silicones), polyurethane, polyacrylate elastomer, chlorinated polyethylene, styrene-isoprene-styrene copolymer (SIS), styrene-butadiene-styrene copolymer (SBS), ethylene-propylene-dienepolymer, and fluoroelastomers, including tetrafluoroethylene propylene, fluorosilicone, and perfluoroelastomer. The polymer matrix can be a single polymer or any mixing of these thermosetting polymers.

FIG. 1B is a second perspective view of the system 100 of FIG. 1, according to some embodiments.

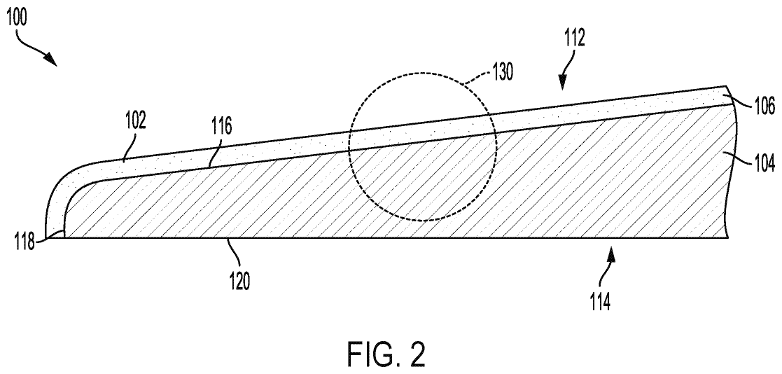

The member 102 may be formed during manufacturing such that the film 106 may be substantially disposed on one side of the member 102. In FIG. 2, the film 106 is substantially disposed on the first side 112 such that the film 106 may not be viewable from the second side 114. In some embodiments, the film 106 may be integrally formed onto the body 104 such that a portion of the film 106 may extend from the first side 112 towards the second side 114. For example, the film 106 may extend beyond the first side 112 and also cover a surface of the member 102 that is located between the first side 112 and second side 114. In another example, a portion of the film 106 may be integrally formed onto the surface of the second side 114.

FIG. 2 is a partial sectional view of system 100 of FIG. 1, according to some embodiments.

The body 104 may be formed to include any of a plurality of shapes and/or profiles. The body 104 may form may be formed such that when installed onto the electrical box, the body 104 may include one or more rounded edges defining a transition from a surface 116 at the first side 112 to a sidewall 118. In some embodiments, the body 104 may also include a transition that extends between the sidewall 118 and surface 120 at the second side 114.

The film 106 may be integrally formed with the body 104 such that the arrangement of film 106 covers the surface 116 and extends beyond the surface 116 and covers the sidewall 118. In FIG. 2, the film 106 is shown arranged covering surface 116 and sidewall 118 and such that the end of film 106 is substantially aligned with surface 120. This sidewall 118 may extend from surface 116 to provide a smooth transition at the edges and help to improve the adhesion of film 106 to the body 104. This may also provide the outer exposed surface of member 102, which may be observable by persons within view of the member 102, with a certain decorative appearance based on the materials of the film 106, as will be further described herein. In some embodiments, the film 106 may be integrally formed with body 104 such that the film 106 substantially covers the surface 116. In other embodiments, the film 106 may be integrally formed with body 104 such that the film 106 covers the surface 116, sidewall 118, and at least a portion of surface 120.

In FIG. 2, area 130 is a portion of member 102 that will be described in further detail below.

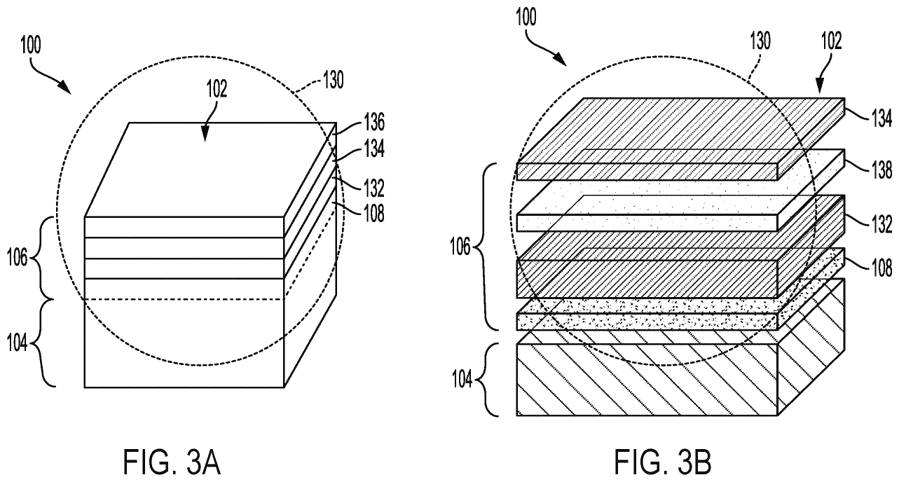

FIG. 3A is a partial sectional view of the system 100 from FIG. 2, according to some embodiments.

In FIG. 3A, area 130 of member 102 is shown including body 104 and film 106. The film 106 may include a plurality of layers arranged on top of each other. The film 106 may include first adhesive layer 108. The first adhesive layer 108, post-manufacturing, is integrally formed with the base resin material at surface 116 of body 104 such that the first adhesive layer affixes the one or more other layers of film 106 to the body 104.

Film 106 may include first adhesive layer 108, graphic layer 132, and hard coat layer 134. The graphic layer 132 may be disposed adjacent the first adhesive layer 108. The graphic layer 132 may include one or more materials having properties configured to provide the surface of member 102 with a certain desired decorative appearance based on the one or more materials. In some embodiments, the graphic layer 132 may include metallic materials having properties configured to provide the member 102 with the appearance of a metallic surface. For example, the film 106 may provide member 102 with the appearance of a brass finish, nickel finish, aluminum finish, gold finish, copper finish, gunmetal finish, steel finish, and other like metals. In other embodiments, the graphic layer 132 may include non-metallics material (e.g., thermoplastics and/or thermosets) having properties configured to provide the member 102 with the appearance of a matte surface or a glossy surface.

In this regard, electrical enclosures and covers may be made of plastics such as member 102 but have the same aesthetics as their metallic counterparts (e.g., conventional metal electrical enclosures) based on utilizing IMD to provide the exterior surface(s) of the electrical enclosure with the desired decorative appearance.

The hard coat layer 134 may be located on a side of the film 106 opposite from the first adhesive layer 108. The hard coat layer 134 may be a transparent or semi-transparent layer configured to protect the other layers of the film 106 and the body 104 from damage caused by sources including ultra-violet radiation, abrasion, dirt, corrosion, and the like. In this regard, the hard coat layer 134 may be formed of one or more materials selected for its ability to protect the other layers and the base material.

The hard coat layer 134 may be selected based on the applications and service conditions of the final part (e.g., member 102). The hard coat layer 134 can be polyurethane or any other specialized films with desirable enhanced abrasion resistance characteristics. The hard coat layer 134 can also have an enhanced hardness (HB2 vs. regular HB1 or nonrated film coating) so that the hard coat layer 134 can resist excessive abrasion. The material of the hard coat layer 134 may also be selected to be compatible with specific service environments, such as demonstrating resistance to humidity, heat, corrosion caused by acidic or alkaline conditions, and the like, depending on the application.

The film 106 may include a carrier film 136. The carrier film 136 may be disposed on a side of film 106 opposite the first adhesive layer 108 (e.g., on the hard coat layer 134), the carrier film 136 being configured to be arranged in the mold during the manufacture of member 102 such that the carrier film 136 contacts the interior surface or surfaces of the mold cavity. In addition, the carrier film 136 may serve as a base layer for processing the film 106 such as, for example, during manufacturing of the film 106 and during installation of the film 106 into the mold. The carrier film 136 may provide an added layer of protection to the film 106, such as during manufacturing, and enables stable fixation of the film 106 during manufacturing. In some embodiments, the carrier film 136 may be a removable film that may be removed from the film 106 and/or member 102 during manufacturing, pre-shipping to a merchant/user, or post-manufacturing.

It is to be appreciated by those having ordinary skill in the art that the thicknesses of the member 102, body 104, film 106, first adhesive layer 108, graphic layer 132, hard coat layer 134, carrier film 136 are exemplary and not intended to be limiting. Each of the components may include any of a plurality of thicknesses in accordance with the present disclosure.

FIG. 3B is an exploded partial sectional view of the system 100 from FIG. 2, according to some embodiments.

The film 106 may include a second adhesive layer 138 located between graphic layer 132 and hard coat layer 134. The second adhesive layer 138 may affix the hard coat layer 134 to the graphic layer 132. In some embodiments, the graphic layer 132 may include one or more layers including the second adhesive layer 138 disposed on a top layer to enable the hard coat layer 134 to attach to the hard coat layer 134. In other embodiments, the hard coat layer 134 may include one or more layers including the second adhesive layer 138 disposed on a bottom layers to enable the hard coat layer 134 to attach to the graphic layer 132.

The materials forming the second adhesive layer 138 may be selected based on the one or more materials forming each of the hard coat layer 134 and graphic layer 132 to enable the second adhesive layer 138 to attach the hard coat layer 134 to the graphic layer 132.

The materials forming the first adhesive layer 108 may be selected based on the one or more materials forming each of the body 104 and graphic layer 132 to enable the first adhesive layer 108 to integrally form with the body 104 and to attach the body 104 to graphic layer 132.

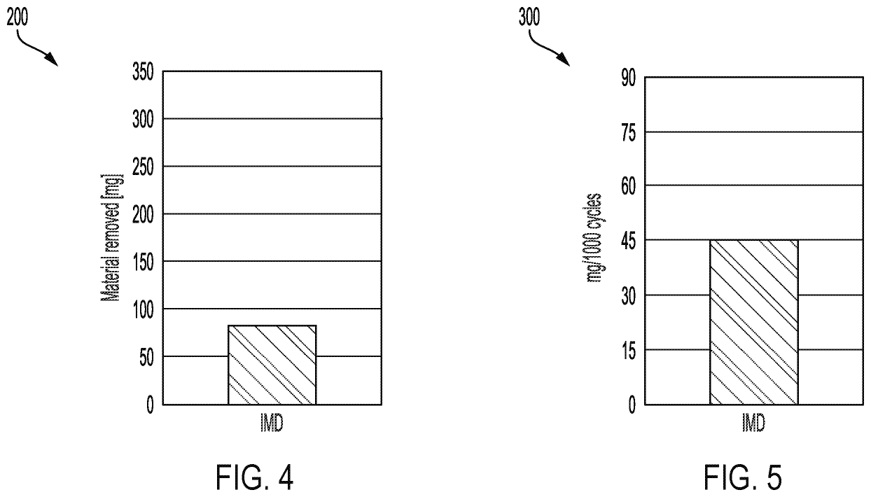

FIG. 4 is a graphical illustration 200 of a non-limiting example of an abrasion resistance of system 100 of FIG. 1, according to some embodiments. FIG. 5 is a graphical illustration 300 of another non-limiting example of the abrasion resistance of system 100 of FIG. 1, according to some embodiments. Unless specifically referenced, FIGS. 4 and 5 will be described collectively.

An abrasion test was applied to film 106. The abrasion test may be, for example, a Taber abrasion test based on ASTM 4060. The abrasion test is used to assess the film 106 anti-abrasion performance. The testing employed wheels with different roughness and then the wheels contact with the targeted surfaces of film 106 and rotate with desired cycles. The sample weight is monitored during the testing. The loss of the coating material of film 106 is recorded in regard to abrasion cycles. The coating abrasion performance is evaluated by wear index. The wear index I is calculated as below:

$$I = \frac{( A - B ) \times 1000}{C}$$

Where, A=weight of test specimen before abrasion, mg; B=weight of test specimen after abrasion, mg; and C=number of cycles of abrasion recorded. In general, the smaller wear index I, the better the coating anti-abrasion performance. The wear index of a non-limiting example embodiment of film 106 are reported in FIGS. 4 and 5 with different abrasion conditions. In both conditions, the film 106 demonstrated superior abrasion resistance relative to other types of conventional protective coating applications and methods such as, for example, powder coated samples. The test indicates the film 106 includes improved abrasion resistance as compared to other types of conventional protective coatings that may be applied to electrical enclosures.

In FIG. 4, the graph 200 shows a non-limiting example embodiment of a film 106 where the wear index was measured with sandpaper 42 at 200 cycles. In this test, the graph 200 shows the film 106 had approximately 75 mg of material removed.

In FIG. 5, the graph 200 shows a non-limiting example embodiment of a film 106 where the wear index was measured with a wheel. In this test, the graph 300 shows the film 106 had approximately 45 mg of material removed per 1000 cycles.

It is to be appreciated by those having ordinary skill in the art that the results shown in FIGS. 4 and 5 for the system 100 and the film 106 are exemplary and not intended to be limiting. In this regard, the wear index of the film 106 may depend on any of a plurality of factors including, but is not limited to, a thickness of each respective layer, the number of layers, the materials of respective layer, other factors, or any combinations thereof.

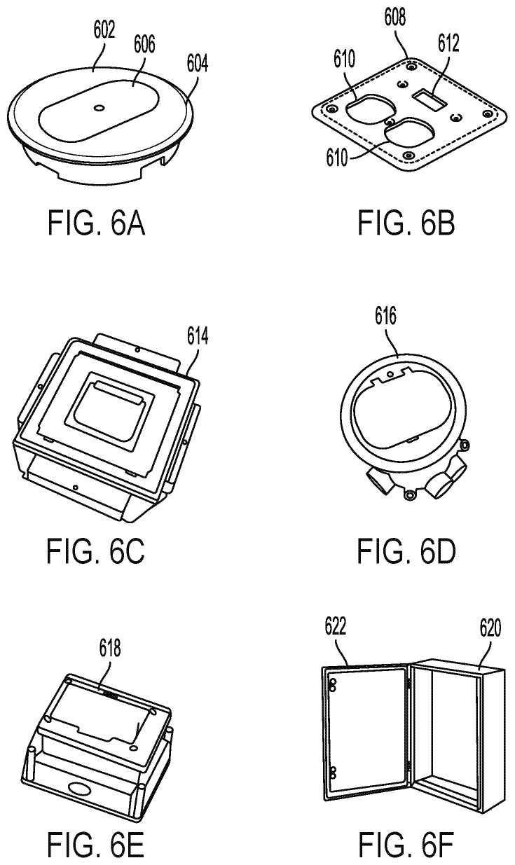

FIG. 6A through FIG. 6F are non-limiting examples of the system 100, according to some embodiments. Unless specifically referenced, FIGS. 6A through 6F will be described collectively.

The electrical enclosure may include member 102 from FIG. 1. The electrical enclosure may be a floor box electrical receptacle and member 102 may be a cover plate for the floor box. The electrical enclosure may also include one or more other members. For example, the system 100 may further include one or more electrical gang cover plates configured to cover an electrical receptacle arranged in the floor box. In FIG. 6A, the cover plate 602 includes a first member 604 configured to cover at least a portion of the floor box and the opening at the structural member (e.g., floor, wall, ceiling, etc.), and may include a second member 606 configured to cover the electrical receptacles of the electrical enclosure. For example, the second member 606 may be installed in the electrical enclosure via fasteners and the second member 606 may open by removing the fasteners to expose the electrical sockets therein.

The member may be a cover plate for an electrical box and may also include one or more openings to enable one or more electrical components to extend through the member. In FIG. 6B, for example, the member 608 may include an opening 610 for accommodating an electrical outlet receptacle (e.g., two receptacles) and an opening 612 for accommodating a light toggle switch.

FIG. 6C through 6E are other non-limiting examples of cover plates for electrical enclosures, each electrical enclosure 614, 616, 618 having a cover plate assembly include one or more members.

In FIG. 6F, the electrical enclosure box 620 may be configured to be installed onto a structural member such that one or more sides of the electrical enclosure box 620 may be viewable by users. The electrical enclosure box 620 may also include an access panel 622 (e.g., door) that may be removed or cause to rotate about one or more hinges to provide access to the interior of the electrical enclosure box 620. In this regard, one or more exterior surfaces of the electrical enclosure box 620 may include the film 106 to provide the exterior of the electrical enclosure box 620 with the desired decorative surface appearance.

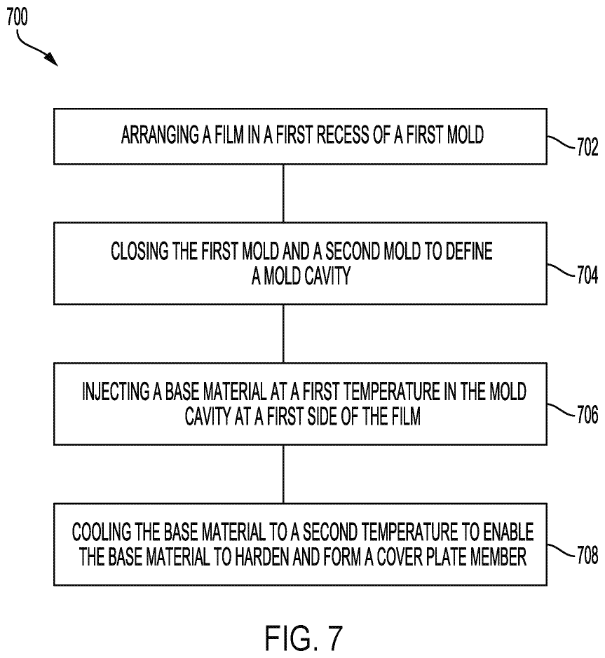

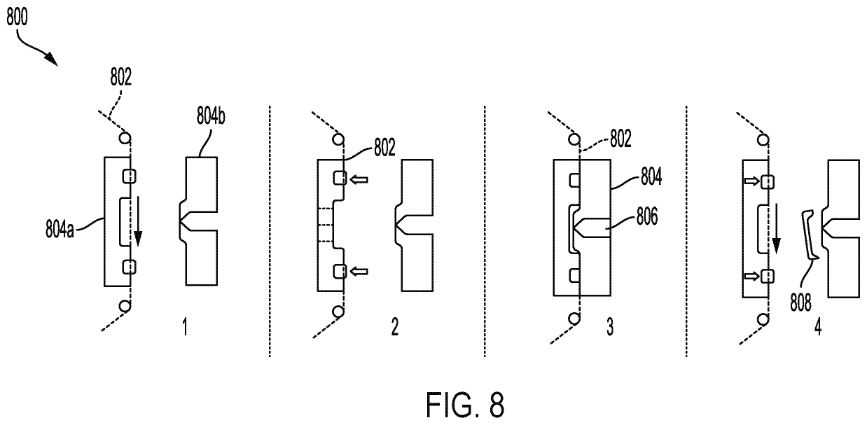

FIG. 7 is a flow diagram illustrating a method 700 of manufacturing an electrical enclosure, according to some embodiments. FIG. 8 is a diagrammatic view of a non-limiting example system for performing the method of FIG. 7, according to some embodiments. The method 700 will be described in conjunction with FIG. 8.

At 702, the method 700 includes arranging a film including a plurality of layers in a first recess of a first mold. The film may include a first adhesive layer. The film may further include a graphic layer, a hard coat layer, and a second adhesive layer. The graphic layer may be located adjacent the first adhesive layer, the first adhesive layer affixing the graphic layer to the base material. In some embodiments, the graphic layer includes one or more materials having properties configured to provide the exterior surface of the cover plate member with a decorative appearance based on the one or more materials. The hard coat layer may be disposed on a side of the film opposite the first adhesive layer. The hard coat layer includes a transparent or semi-transparent protective layer to protect the cover plate member and the other layers of the film. The second adhesive layer may be disposed between the graphic layer and the hard coat layer, the second adhesive layer affixing the hard coat layer to the graphic layer.

The mold may include a first mold and a second mold, the first mold including the first recess. The first and second mold may be joined together and act in cooperation with each other to define a mold cavity for forming a body of a cover plate member such as, for example, the member 102 as shown in FIG. 1. In FIG. 8, the film is shown as film 802, the mold is shown as mold 804, and the cover plate member is shown as member 808. The mold 804 include the first mold (moving mold) 804 a, and the second mold (stationary mold) 804 b, the first mold 804 a and the second mold 804 b act in cooperation to define the mold cavity for forming the member 808 when positioned against the other of the first mold 804 a and the second mold 804 b, according to some embodiments. In some embodiments, the mold may include one or more other members acting in cooperation with the first mold and the second mold to form the body. For example, the mold 804 may include four members that act in cooperation to form the member 808.

At 704, the method 700 includes closing the first mold and second mold such that the first recess and a portion of the second mold defines a mold cavity. The mold cavity may be defined by the first recess of the first mold and a surface of the second mold. In some embodiments, the mold cavity may be defined by the first recess and a portion of the surface of the second mold. In other embodiments, the second mold may include one or more portions protruding from the surface and having dimensions configured to define the dimensions of the mold cavity for forming the cover plate members.

At 706, the method 700 includes injecting a base material at a first temperature in the mold cavity at a first side of the film. The film may be positioned along one or more sides of the first recess, and the base material may be injected into the mold cavity (i.e., interior space defined by the mold) such that the base material substantially fills the mold cavity. The first temperature may correspond to a melting temperature of the base material such that the base material forms a flowable material at the first temperature. The base material may be heated to the melting temperature to enable the plastic melt base material to flow into the mold cavity during the injection and for the flowable base material to conform to the interior dimensions of the mold cavity with the film being disposed between the base material and the one or more sides of the mold cavity. In some embodiments, the first temperature may also be greater than a glass transition temperature of a first adhesive layer of the film to enable the first adhesive layer to integrally form with the base material. The base material is shown as base material 806 in FIG. 8.

At 708, the method 700 includes cooling the base material to a second temperature to enable the base material to harden and form the cover plate member. When the base material reaches the second temperature, the base material may harden, thereby integrally forming the film with the base material to form the cover plate member. The base material may harden at a second temperature, the second temperature corresponding to an ejection temperature for the specific base material/plastic being molded. In some embodiments, the first temperature may be greater than the glass transition temperature of the first adhesive layer, and less than the melting temperature of the first adhesive layer.

At the first temperature, the first adhesive layer of the film may integrally fuse with the base material such that the film defines an exterior surface of the base material body. At the second temperature, the hardened base material may act in cooperation with the first adhesive layer to affix the one or more other layers of the film to the surface of the base material such that the base material and the film forms the cover plate member. That is, the second temperature may be an ejection temperature at which the plastic melt base material hardens, thereby enabling the material of the first adhesive layer to permanently fuse with the base material.

In some embodiments, the cover plate member may include a first member. The first member may be configured to cover an opening defined by an electrical enclosure housing such as, for example, member 102 as shown in FIG. 1. The cover plate member may also include a second member. In some embodiments, the cover plate member may include one or more second members. The second members may be configured to cover openings defined by first member. The first member and the one or more second members may each include the film integrally formed with the base material such that the film defines the exterior surface of a respective one of the first member or the one or more second members, that is, the first member and the second members may be formed by molding the base material and the film using the same molding process.

In some embodiments, the cover plate may also be configured to cover an opening in a structural member when the cover plate is installed onto the electrical enclosure. In this regard, the cover plate may cover the opening of the structural member and the opening of the electrical enclosure opening to conceal the one or more electrical components in the electrical enclosure housing.

In some embodiments, the method 700 may further include removing the body from the mold and performing further refining steps to form the member. In this regard, when the member is formed by the hardening of the base material at the second temperature and including the film integrally formed on the surface of the body, excess film may extend from the edges.

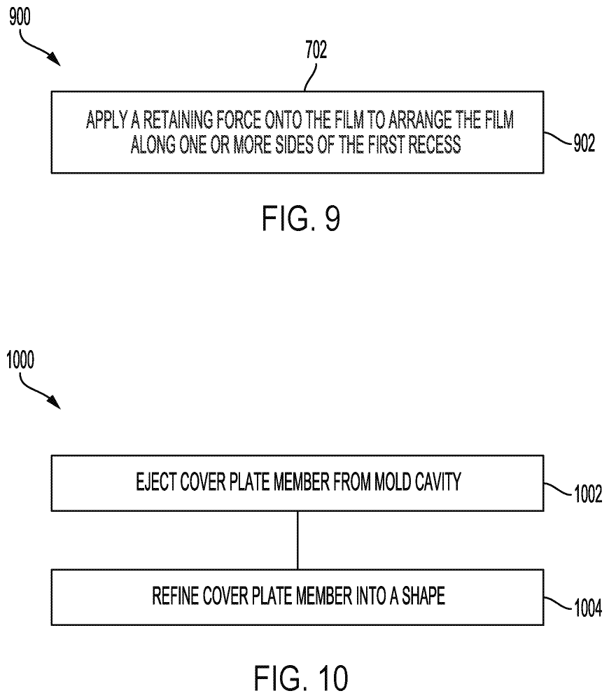

FIG. 9 is a flow diagram illustrating a method 900 of manufacturing the electrical enclosures, according to some embodiments. The method 900 may be a further embodiment of method 700. The method 900 will be described in conjunction with FIG. 8.

At 902, the method 900 includes applying a retaining force onto the film to arrange the position of the film along one or more sides of the first recess. The retaining force may be applied to the film to retain the film in the mold cavity along one or more interior sides. The force may also enable the base material to be injected into the mold cavity such that the base material may substantially fill the mold cavity and so that the film may not impede the filling of the mold cavity. In some embodiments, the retaining force may include mechanical forces, electrostatic association, gravity force, vacuum forces, and other like methods. In other embodiments the retaining force may include at least one of mechanical forces, electrostatic associations, gravity force, and vacuum forces.

FIG. 10 is a flow diagram illustrating a method 1000 of manufacturing the electrical enclosures, according to some embodiments. The method 1000 may be a further embodiment of method 700 and method 800. The method 1000 will be described in conjunction with FIG. 8.

At 1002, the method 1000 includes ejecting the cover plate member from the mold. The cover plate member may be ejected from the mold cavity. In some embodiments, the cover plate member may be ejected from the mold cavity by applying a second force onto the cover plate member configured to eject the cover plate member from the mold cavity, that is, to eject the cover plate member from the first recess or from the protrusions of the second mold. In some embodiments, the cover plate member may include a first shape. The first shape may include an excess film. For example, the excess film may extend beyond the edges of the body formed by the base material.

At 1004, the method 1000 includes refining the cover plate member to define a second shape. Refining the cover plate member includes removing the excess film from one or more edges of the cover plate having the first shape to define the second shape. In this regard, the second shape may have the excess film removed such that the film is located on a surface of the cover plate member. In some embodiments, in the second shape, the film may be located on one or more surfaces of the cover plate member. For example, the film may be located on a first surface and one or more sidewalls. The excess film may be removed by any of a plurality of processes including, but not limited to, cutting, scraping, shaving, melting, or other similar methods.

All prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements;
disposed indirectly between both of the two other structural elements such that the particular structural component is not in direct contact with both of the two other structural elements, and other features can be disposed therebetween; or
any combination(s) thereof.

As used herein “embedded” means that a first material is distributed throughout a second material.

### Aspects

Various Aspects are described below. It is to be understood that any one or more of the features recited in the following Aspect(s) can be combined with any one or more other Aspect(s).

Aspect 1. A system for an electrical enclosure comprising: one or more members comprising: a base material; and a film including a plurality of layers, the film comprising: a first adhesive layer; wherein a portion of the first adhesive layer is integrally formed with the base material and affixes the other layers of the film to the base material to define an exterior surface of the one or more members; wherein the one or more members comprises a cover plate member for the electrical enclosure.

Aspect 2. The system according to aspect 1, wherein the one or more members further comprises at least one plate member for covering an electrical receptacle opening.

Aspect 3. The system according to any of the preceding aspects, wherein the film further comprises: a graphic layer, wherein the graphic layer is disposed on the first adhesive layer opposite the base material, and the graphic layer comprises one or more materials having properties configured to provide the exterior surface of the one or more members with a decorative appearance based on the one or more materials.

Aspect 4. The system according to aspect 3, wherein the first adhesive layer affixes the graphic layer to the exterior surface of the one or more members.

Aspect 5. The system according to aspects 3 or 4, wherein the graphic layer comprises: a metallic material, wherein the properties of the metallic material are configured to provide the one or more members with a metallic surface.

Aspect 6. The system according to aspects 3, 4, or 5, wherein the graphic layer comprises: a plastic material, wherein the properties of the plastic material are configured to provide the one or more members with a matte surface or a glossy surface.

Aspect 7. The system according to aspects 3, 4, 5, or 6, wherein the film further comprises: a hard coat layer, wherein the hard coat layer comprises a transparent or semi-transparent protective layer disposed on a side of the film opposite the first adhesive layer, and a second adhesive layer, wherein the second adhesive layer is arranged between the graphic layer and the hard coat layer.

Aspect 8. The system according to aspect 7, wherein the hard coat layer is configured to protect the one or more members and the other layers of the film from ultra-violet radiation, abrasion, dirt, and corrosion; wherein the second adhesive layer affixes the hard coat layer to the graphic layer.

Aspect 9. The system according to any of the preceding aspects, wherein the one or more members are formed using a molding process, the molding process comprising injecting the base material into a mold at a first temperature to enable the portion of the first adhesive layer contacting the base material to integrally fuse with the base material and form a respective member of the one or more members when the base material hardens to a second temperature.

Aspect 10. An apparatus comprising: an electrical enclosure, wherein the electrical enclosure includes a housing for receiving one or more electrical components therein, and at least one member comprising: a base plastic material, and a film comprising: a first adhesive layer, and a graphic layer; wherein a portion of the first adhesive layer is integrally formed with the base plastic material and affixes the graphic layer to the base plastic material to define an exterior surface of the at least one member; wherein the at least one member comprises a first member configured to cover an opening of the housing.

Aspect 11. The apparatus according to aspect 10, wherein the graphic layer is disposed on the first adhesive layer opposite the base plastic material, and the graphic layer comprises one or more materials having properties configured to provide the exterior surface of the first member with a decorative appearance based on the one or more materials.

Aspect 12. The apparatus according to aspect 11, wherein the graphic layer comprises at least one of: a metallic material, wherein the metallic material comprises properties configured to provide the exterior surface of the at least one member with a metallic appearance, and a plastic material, wherein the plastic material comprises properties configured to provide the exterior surface of the at least one member with a matte appearance or a glossy appearance.

Aspect 13. The apparatus according to aspects 10, 11, or 12, wherein the film further comprises: a hard coat layer, wherein the hard coat layer comprises a transparent or semi-transparent protective layer disposed on a side of the film opposite the first adhesive layer, wherein the hard coat layer protects the at least one member from ultra-violet radiation, abrasion, dirt, and corrosion, and a second adhesive layer, wherein the second adhesive layer is arranged between the graphic layer and the hard coat layer to affix the hard coat layer to the graphic layer.

Aspect 14. The apparatus according to aspects 10, 11, 12, or 13, wherein the at least one member further comprises: one or more second members, wherein the one or more second members are configured to cover an opening of the first member.

Aspect 15. A method for manufacturing a cover plate member for an electrical enclosure comprising: arranging a film comprising a plurality of layers in a first recess of a first mold; closing the first mold and a second mold such that the first recess and a portion of the second mold defines a mold cavity; injecting a base material at a first temperature in the mold cavity at a first side of the film; and cooling the base material to a second temperature to enable the base material to harden and form the cover plate member, the film defining an exterior surface of the cover plate member; wherein the film comprises a first adhesive layer, a portion of the first adhesive layer integrally forming with the base material at the first temperature to enable the first adhesive layer to affix the other layers of the film to the exterior surface of the cover plate member.

Aspect 16. The method according to aspect 15, wherein the method further comprises: applying a retaining force onto the film to arrange the film along one or more sides of the first recess, wherein the retaining force comprises at least one of mechanical force, electrostatic association, gravity, and vacuum.

Aspect 17. The method according to aspects 15 or 16, the method further comprising: ejecting the cover plate member from the mold cavity, wherein the cover plate member is ejected having a first shape; and refining the cover plate member to define a second shape, wherein refining the cover plate member comprises removing excess film from one or more edges of the cover plate member having the first shape to define the second shape.

Aspect 18. The method according to aspects 15, 16, or 17, wherein the first temperature corresponds to a melting temperature of the base material such that the base material comprises a flowable material at the first temperature, and wherein the first temperature is greater than a glass transition temperature of the first adhesive layer to enable the first adhesive layer to integrally form with the base material; wherein the second temperature comprises an ejection temperature, the second temperature being below the glass transition temperature of the first adhesive layer.

Aspect 19. The method according to aspects 15, 16, 17, or 18, wherein the film further comprises: a graphic layer disposed adjacent the first adhesive layer opposite the base material, wherein the graphic layer comprises one or more materials having properties configured to provide the exterior surface of the cover plate member with a decorative appearance based on the one or more materials, a hard coat layer disposed on a side of the film opposite the first adhesive layer, wherein the hard coat layer comprises a transparent or semi-transparent protective layer to protect the cover plate member and the other layers of the film, and a second adhesive layer disposed between the graphic layer and the hard coat layer, wherein the second adhesive layer affixes the hard coat layer to the graphic layer.

Aspect 20. The method according to aspects 15, 16, 17, 18, or 19, wherein the cover plate member comprises: a first member, and one or more second members, wherein the first member and the one or more second members each comprises the film integrally formed with the base material to define the exterior surface of a respective one of the cover plate member.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A system for an electrical enclosure comprising:
one or more members comprising:
a base material; and
a film including a plurality of layers, the film comprising:
a first adhesive layer;
wherein a portion of the first adhesive layer is integrally formed with the base material and affixes the other layers of the film to the base material to define an exterior surface of the one or more members;
wherein the one or more members comprises a cover plate member for the electrical enclosure.

2. The system of claim 1, wherein the one or more members further comprises at least one plate member for covering an electrical receptacle opening.

3. The system of claim 1, wherein the film further comprises:
a graphic layer,
wherein the graphic layer is disposed on the first adhesive layer opposite the base material, and the graphic layer comprises one or more materials having properties configured to provide the exterior surface of the one or more members with a decorative appearance based on the one or more materials.

4. The system of claim 3, wherein the first adhesive layer affixes the graphic layer to the exterior surface of the one or more members.

5. The system of claim 3, wherein the graphic layer comprises:
a metallic material,
wherein the properties of the metallic material are configured to provide the one or more members with a metallic surface.

6. The system of claim 3, wherein the graphic layer comprises:
a plastic material,
wherein the properties of the plastic material are configured to provide the one or more members with a matte surface or a glossy surface.

7. The system of claim 3, wherein the film further comprises:
a hard coat layer,
wherein the hard coat layer comprises a transparent or semi-transparent protective layer disposed on a side of the film opposite the first adhesive layer, and
a second adhesive layer,
wherein the second adhesive layer is arranged between the graphic layer and the hard coat layer.

8. The system of claim 7, wherein the hard coat layer is configured to protect the one or more members and the other layers of the film from ultra-violet radiation, abrasion, dirt, and corrosion;
wherein the second adhesive layer affixes the hard coat layer to the graphic layer.

9. The system of claim 8, wherein the one or more members are formed using a molding process, the molding process comprising injecting the base material into a mold at a first temperature to enable the portion of the first adhesive layer contacting the base material to integrally fuse with the base material and form a respective member of the one or more members when the base material hardens to a second temperature.

10. An apparatus comprising:
an electrical enclosure,
wherein the electrical enclosure includes a housing for receiving one or more electrical components therein, and
at least one member comprising:
a base plastic material, and
a film comprising:
a first adhesive layer, and
a graphic layer;
wherein a portion of the first adhesive layer is integrally formed with the base plastic material and affixes the graphic layer to the base plastic material to define an exterior surface of the at least one member;
wherein the at least one member comprises a first member configured to cover an opening of the housing.

11. The apparatus of claim 10, wherein the graphic layer is disposed on the first adhesive layer opposite the base plastic material, and the graphic layer comprises one or more materials having properties configured to provide the exterior surface of the first member with a decorative appearance based on the one or more materials.

12. The apparatus of claim 11, wherein the graphic layer comprises at least one of:
a metallic material,
wherein the metallic material comprises properties configured to provide the exterior surface of the at least one member with a metallic appearance, and
a plastic material,
wherein the plastic material comprises properties configured to provide the exterior surface of the at least one member with a matte appearance or a glossy appearance.

13. The apparatus of claim 10, wherein the film further comprises:
a hard coat layer,
wherein the hard coat layer comprises a transparent or semi-transparent protective layer disposed on a side of the film opposite the first adhesive layer,
wherein the hard coat layer protects the at least one member from ultra-violet radiation, abrasion, dirt, and corrosion, and
a second adhesive layer,
wherein the second adhesive layer is arranged between the graphic layer and the hard coat layer to affix the hard coat layer to the graphic layer.

14. The apparatus of claim 10, wherein the at least one member further comprises:
one or more second members,
wherein the one or more second members are configured to cover an opening of the first member.

15. A method for manufacturing a cover plate member for an electrical enclosure comprising:
arranging a film comprising a plurality of layers in a first recess of a first mold;
closing the first mold and a second mold such that the first recess and a portion of the second mold defines a mold cavity;
injecting a base material at a first temperature in the mold cavity at a first side of the film; and
cooling the base material to a second temperature to enable the base material to harden and form the cover plate member, the film defining an exterior surface of the cover plate member;
wherein the film comprises a first adhesive layer, a portion of the first adhesive layer integrally forming with the base material at the first temperature to enable the first adhesive layer to affix the other layers of the film to the exterior surface of the cover plate member.

16. The method of claim 15, wherein the method further comprises:
applying a retaining force onto the film to arrange the film along one or more sides of the first recess,
wherein the retaining force comprises at least one of mechanical force, electrostatic association, gravity, and vacuum.

17. The method of claim 15, the method further comprising:
ejecting the cover plate member from the mold cavity,
wherein the cover plate member is ejected having a first shape; and
refining the cover plate member to define a second shape,
wherein refining the cover plate member comprises removing excess film from one or more edges of the cover plate member having the first shape to define the second shape.

18. The method of claim 15, wherein the first temperature corresponds to a melting temperature of the base material such that the base material comprises a flowable material at the first temperature, and wherein the first temperature is greater than a glass transition temperature of the first adhesive layer to enable the first adhesive layer to integrally form with the base material;
wherein the second temperature comprises an ejection temperature, the second temperature being below the glass transition temperature of the first adhesive layer.

19. The method of claim 15, wherein the film further comprises:
a graphic layer disposed adjacent the first adhesive layer opposite the base material,
wherein the graphic layer comprises one or more materials having properties configured to provide the exterior surface of the cover plate member with a decorative appearance based on the one or more materials,
a hard coat layer disposed on a side of the film opposite the first adhesive layer,
wherein the hard coat layer comprises a transparent or semi-transparent protective layer to protect the cover plate member and the other layers of the film, and
a second adhesive layer disposed between the graphic layer and the hard coat layer,
wherein the second adhesive layer affixes the hard coat layer to the graphic layer.

20. The method of claim 19, wherein the cover plate member comprises:
a first member, and
one or more second members,
wherein the first member and the one or more second members each comprises the film integrally formed with the base material to define the exterior surface of a respective one of the cover plate member.
